(19) United States
(12) Patent Application Publication
(10) Pub. No.: US 2014/0083485 A1
(43) Pub. Date: Mar. 27, 2014

(54) Photovoltaic Assembly And Associated Methods

(71) Applicant: Ascent Solar Technologies, Inc., Thornton, CO (US)

(72) Inventors: Dana Steven Nance, Fort Collins, CO (US); Jason Michael Messing, Denver, CO (US); Quinn Alan Quintana, Colorado Springs, CO (US); Kevin Foerchinger, Longmont, CO (US); Robert Clare Meck, Fort Collins, CO (US)

(73) Assignee: Ascent Solar Technologies, Inc., Thornton, CO (US)

(21) Appl. No.: 14/038,096

(22) Filed: Sep. 26, 2013

Related U.S. Application Data
(60) Provisional application No. 61/706,501, filed on Sep. 27, 2012.

(51) Int. Cl. H01L 31/02; H01L 31/05; H01L 31/0224

(52) U.S. Cl. CPC H01L 31/0201; H01L 31/022425; H01L 31/0504
USPC 136/249; 136/256; 136/244; 438/66

(57) ABSTRACT

A photovoltaic assembly includes a flexible photovoltaic module, a flexible back barrier layer, and electrically conductive first and second flexible bus bars. The photovoltaic module includes opposing front and back outer surfaces and first and second electrical contacts on the front outer surface. The photovoltaic module is adapted to generate an electrical potential difference between the first and second electrical contacts in response to light incident on the front outer surface. The flexible back barrier layer is disposed on the back outer surface of the photovoltaic module. The electrically conductive first and second flexible bus bars are electrically coupled to the first and second electrical contacts, respectively, and the first and second flexible bus bars wrap around the flexible photovoltaic module and extend through the back barrier layer.

### RELATED APPLICATIONS

This application claims benefit of priority to U.S. Provisional Patent Application Ser. No. 61/706,501, filed Sep. 27, 2012, which is incorporated herein by reference.

### BACKGROUND

Mobile electronic devices, such as mobile telephones, tablet computers, and laptop computers, have come very popular. Almost all of these devices rely on rechargeable batteries, such as lithium ion batteries, for electric power. Due to the desire to minimize mobile electronic device size, weight, and cost, as well as limitations of conventional battery technology, mobile electronic device batteries typically have a small capacity and therefore must be frequently recharged. For example, batteries of some mobile telephones, such as mobile telephones with advanced processors designed to run a wide variety of applications, may need to be recharged more than once per day during periods of extensive device use. Recharging a battery typically requires that the battery be electrically coupled to a fixed electric power source, such as a building's electrical outlet, via a power converter commonly referred to as a “charger” or an “adaptor,” thereby impairing the device's mobility. Accordingly, it is desirable to minimize mobile electronic device battery charging from a fixed power source.

One possible way of reducing the need to charge a mobile electronic device's battery from a fixed power source is to couple a photovoltaic assembly to the mobile electronic device. The photovoltaic assembly generates an electric current in response to incident light, and the electric current charges the device's battery, and/or directly powers the device. Accordingly, coupling a photovoltaic assembly to an electronic mobile device may reduce, or even eliminate, the need to recharge the battery from a fixed power source.

Protective cases including photovoltaic assemblies have been proposed, for example, for use with mobile telephones and tablet computers. However, conventional photovoltaic assemblies are typically large and inflexible. Thus, cases incorporating these photovoltaic assemblies are typically bulky, thereby impairing the mobility, industrial design, and/or aesthetic properties of the mobile device that they are coupled to. For instance, one conventional mobile telephone case including a photovoltaic assembly is almost as thick as the mobile telephone itself, thereby significantly increasing the effective size and drastically changing industrial design of the telephone coupled to it. Additionally, many conventional photovoltaic assemblies are fragile, thereby necessitating bulky and/or expensive means for protecting the assemblies in mobile electronic device applications.

### SUMMARY

In an embodiment, a photovoltaic assembly includes a flexible photovoltaic module, a flexible back barrier layer, and electrically conductive first and second flexible bus bars. The photovoltaic module includes opposing front and back outer surfaces and first and second electrical contacts on the front outer surface. The photovoltaic module is adapted to generate an electrical potential difference between the first and second electrical contacts in response to light incident on the front outer surface. The flexible back barrier layer is disposed on the back outer surface of the photovoltaic module. The electrically conductive first and second flexible bus bars are electrically coupled to the first and second electrical contacts, respectively, and the first and second flexible bus bars wrap around the flexible photovoltaic module and extend through the back barrier layer.

In an embodiment, a method for forming a photovoltaic assembly includes the following steps: (a) attaching first and second flexible bus bars to respective electrical contacts on a front outer surface of a flexible photovoltaic module; (b) wrapping the first and second flexible bus bars around the flexible photovoltaic module; (c) threading the first and second flexible bus bars through at least one aperture in a flexible back adhesion layer and at least one aperture in a flexible back barrier layer; and (d) attaching the back barrier layer to a back outer surface of the photovoltaic module using the back adhesion layer, the back outer surface of the photovoltaic module opposing the front outer surface of the photovoltaic module.

### BRIEF DESCRIPTION OF THE DRAWINGS

FIG. 1 shows a front perspective view of a photovoltaic assembly, according to an embodiment.

FIG. 2 shows a back perspective view of the FIG. 1 photovoltaic assembly.

FIG. 3 shows an exploded perspective view of the FIG. 1 photovoltaic assembly.

FIG. 4 shows a top plan view of a photovoltaic module of the FIG. 1 photovoltaic assembly.

FIG. 5 shows a method for forming a photovoltaic assembly, according to an embodiment.

FIG. 6 shows a back perspective view of an alternate embodiment of the FIG. 1 photovoltaic assembly.

FIG. 7 shows a back perspective view of another alternate embodiment of the FIG. 1 photovoltaic assembly.

### DETAILED DESCRIPTION OF THE EMBODIMENTS

Applicants have developed photovoltaic assemblies conducive for use in mobile electronic device applications, such as mobile telephone, tablet computers, and/or laptop computer applications. For instance, certain embodiments of the photovoltaic assemblies are thin, lightweight, flexible, and/or aesthetically pleasing. These properties potentially enable the photovoltaic assemblies to be coupled to a mobile electronic device with minimal increase in effective device size and weight, and/or with minimal change to the device's industrial design.

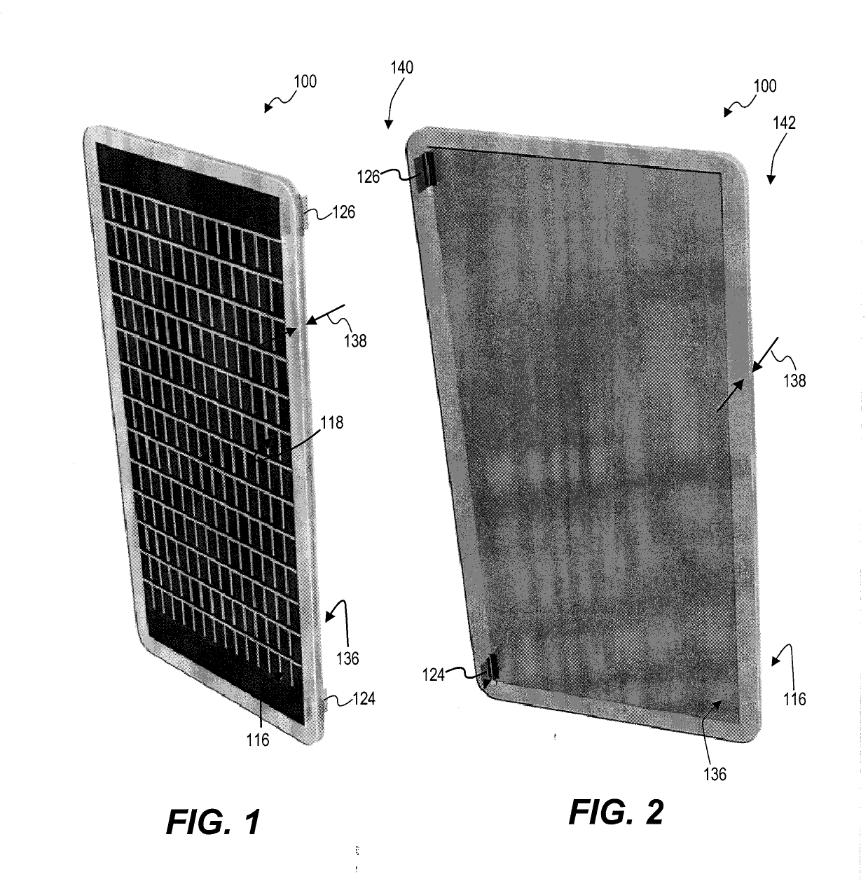

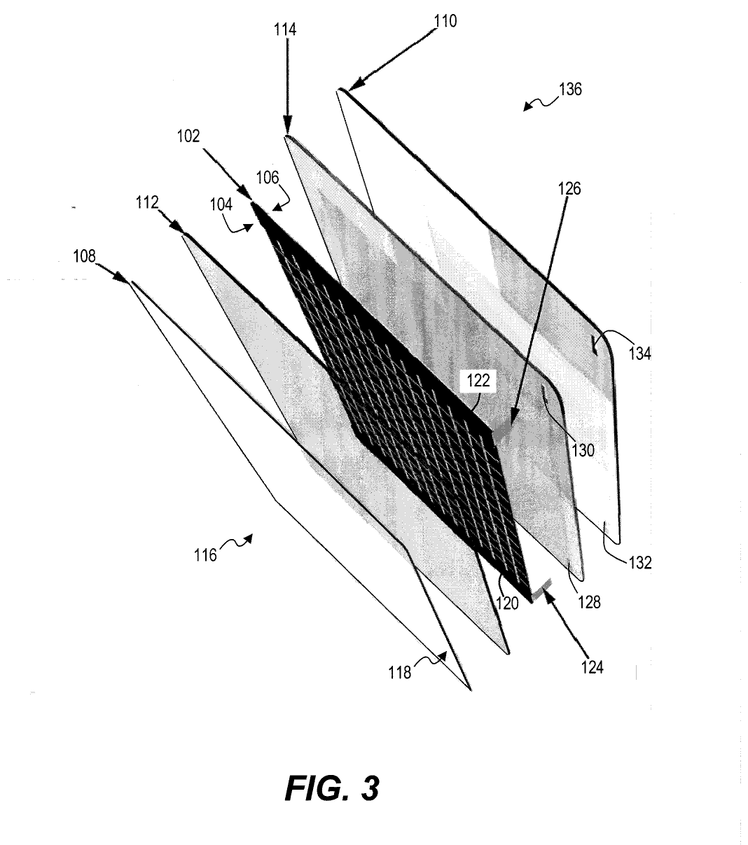

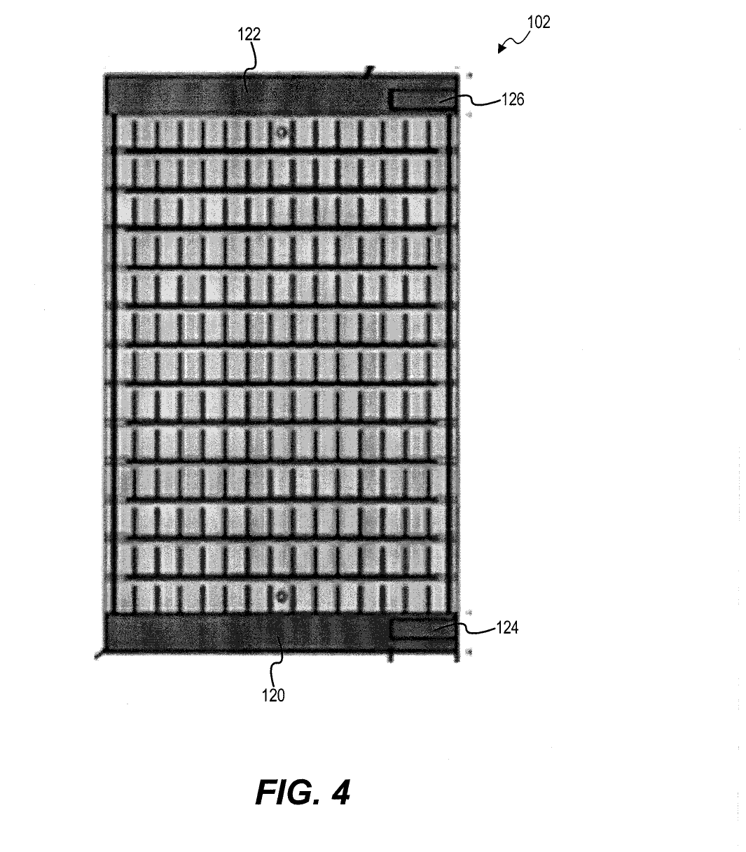

FIGS. 1 and 2 show a front perspective view and a back perspective view, respectively, of a photovoltaic assembly 100. FIG. 3 shows an exploded perspective view of assembly 100, and FIG. 4 shows a top plan view of a photovoltaic module 102 of the photovoltaic assembly. FIGS. 1-4 are best viewed together in the following discussion.

Photovoltaic assembly 100 includes flexible photovoltaic module 102 with opposing front and back outer surfaces 104, 106, a flexible front barrier layer 108 disposed on front outer surface 104, and a flexible back barrier layer 110 disposed on back outer surface 106. Front and back barrier layers 108, 110 protect photovoltaic module 102 from environmental elements, such as moisture, dirt, and mechanical force. Front barrier layer 108 is secured to front outer surface 104 by a front adhesion layer 112 disposed therebetween, and back barrier layer 110 is secured to back outer surface 106 by a back adhesion layer 114 disposed therebetween. Front barrier layer 108 and front adhesion layer 112 are each optically transparent to allow light incident on a front side 116 of assembly 100 to reach module front outer surface 104. In some embodiments, an outer surface 118 of front barrier layer 108 is substantially smooth, thereby potentially eliminating the need for an additional material layer in applications requiring a smooth outer surface.

Photovoltaic module 102 includes a plurality of photovoltaic cells electrically coupled to first and second electrical contacts 120, 122 on module front outer surface 104. Accordingly, light incident on front outer surface 104 will generate an electrical potential difference between first and second electrical contacts 120, 122, such that an electric current will flow in an electrical circuit electrically coupled across contacts 120, 122. An electrically conductive first bus bar 124 is electrically coupled to first electrical contact 120, and an electrically conductive second bus bar 126 is electrically coupled to second electrical contact 122. First and second bus bars 124, 126 are formed, for example, of electrically conductive tape, such as metallic foil tape having substantially rectangular cross-section or fabric tape including metallic components. In some embodiments where first and second bus bars 124, 126 are formed of electrically conductive tape, the bus bars are affixed to first and second electrical contacts 120, 122, respectively, at least partially by adhesive material of the tape. Use of tape adhesive material to secure bus bars 124, 126 to contacts 120, 122 may provide an option to soldering the bus bars to the electrical contacts, thereby promoting manufacturing simplicity and low cost. Bus bars 124, 126 can be soldered to electrical contacts 120, 122, though, without departing from the scope hereof.

First and second bus bars 124, 126 wrap around photovoltaic module 102 and extend through respective apertures 128, 130 in back adhesion layer 114, as well as through respective apertures 132, 134 in back barrier layer 110, such that bus bars 124, 126 terminate on a back side 136 of assembly 100. A passivation material, such as an encapsulant or pottant material, is optionally disposed in apertures 128, 130, 132, 134 to seal the apertures and prevent environmental contaminants from infiltrating assembly 100. In certain alternate embodiments, apertures 128 and 130 are combined into a single aperture, and/or apertures 132, 134 are combined into a single aperture, to reduce manufacturing complexity, with the possible tradeoff of increased aperture area and increased likelihood of bus bars 124, 126 shorting together.

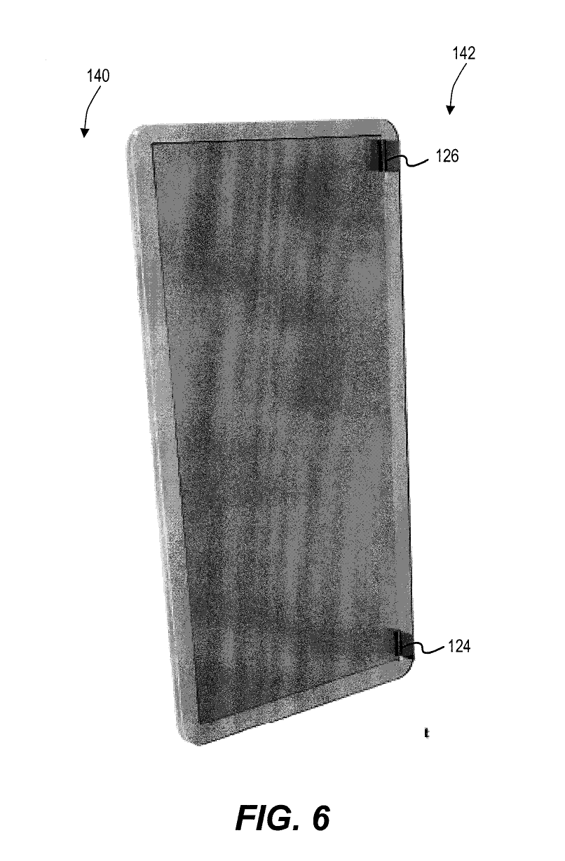

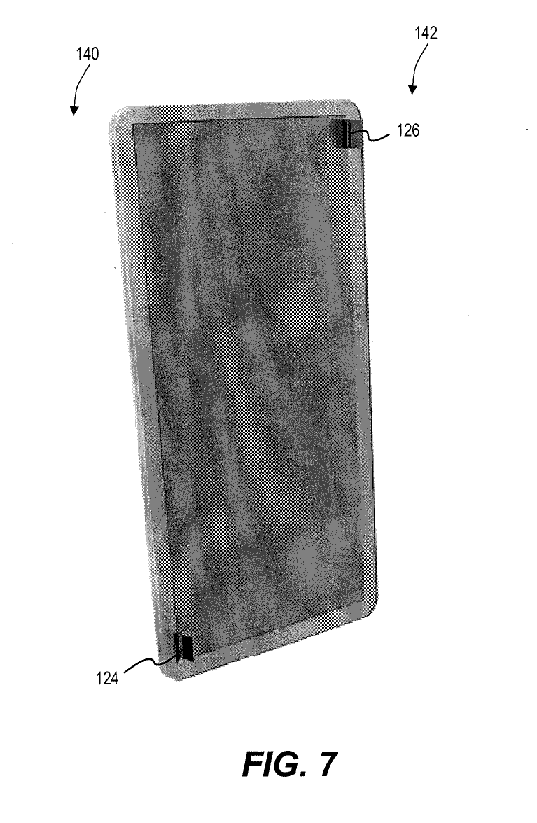

First and second bus bars extend from a left side 140 of assembly 100, as seen from assembly back side 136, as shown in FIG. 2. However, in some alternate embodiments, first and second bus bars 124, 126 instead extend from a right side 142 of assembly 100, or from alternate sides of assembly 100, as seen from assembly back side 136. For example, FIG. 6 shows back perspective view of an alternate embodiment of assembly 100 where bus bars 124, 126 extend from right side 142, and FIG. 7 shows a back perspective of another alternate embodiment of assembly 100 where bus bars 124, 126 extend from opposing sides 140, 142 of assembly 100.

Photovoltaic assembly 100 may achieve one or more significant advantages that could not be realized by conventional photovoltaic assemblies. For example, the fact that bus bars 124, 126 terminate on back side 136 of assembly 100 (opposite of light sensitive front side 116) facilitates coupling the bus bars to electrical circuitry, such as battery charging control circuitry, disposed behind assembly 100. It is often desired, or even required, that electrical circuitry associated with a photovoltaic assembly be disposed behind the assembly to prevent the circuitry from blocking light to the assembly and to minimize system surface area.

Additionally, the fact that bus bars 124, 126 are integrated in assembly 100 eliminates the need to attach external bus bars to assembly 100, thereby promoting ease of integration of assembly 100 into a system, small system size, and/or pleasing aesthetic properties. Conventional photovoltaic assemblies, in contrast, are typically electrically coupled to electrical circuitry via external bus bars connected to the front (light sensitive) side of the assembly. These external bus bars typically increase system thickness and cause the assembly front surface to have raised features, which are undesirable in many applications. Additionally, the external bus bars may be aesthetically undesirable.

Furthermore, assembly 100's configuration promotes small assembly thickness 138, while still protecting photovoltaic assembly 102 from environmental elements. As shown in FIG. 3, certain embodiments of assembly 100 include as few as three different layers, excluding adhesion layers, thereby potentially allowing assembly 100 to be relatively thin. A small assembly thickness 138, in turn, may enable coupling of assembly 100 to a mobile electronic device without substantially increasing effective device thickness or substantially changing the device's industrial design.

Moreover, the fact that assembly 100's constituent elements are flexible results in assembly 100 being flexible. Such flexibility promotes durability of assembly 100 by potentially allowing it to bend, as opposed to break, when subject to mechanical force. Additionally, the fact that assembly 100 is flexible potentially allows assembly 100 to conform to a non-planar surface.

In certain embodiments, the plurality of photovoltaic cells of photovoltaic module 102 are monolithically integrated on a common substrate. Monolithic integration potentially enables customization of module output voltage and output current ratings during module design, thereby allowing assembly 100 to be tailored to its intended application. Additionally, monolithic integration promotes small module size and pleasing aesthetic properties by reducing pitch between adjacent photovoltaic cells, as well by reducing or eliminating use of discrete bus bars to connect adjacent cells, relative to non-monolithically integrated photovoltaic modules.

In the context of this document, monolithically integrated means that the plurality of photovoltaic cells are formed of a common stack of thin film layers disposed on the substrate, where the stack includes (1) insulating scribes to separate adjacent photovoltaic cells or portions of photovoltaic cells, and (2) conductive vias to electrically couple layers of the stack. Thus, the stack of thin film layers is “patterned” with insulating scribes and “connected” with conductive vias to form a plurality of electrically-interconnected photovoltaic cells. The photovoltaic cells are electrically coupled in series, in parallel, or in series-parallel. One example of monolithic integration techniques that may be used to form photovoltaic module 102 is disclosed in U.S. Patent Application Publication Number 2008/0314439 to Misra (Misra Publication), which is incorporated herein by reference. It should be understood, though, that photovoltaic module 102 may be formed using techniques other than, or in addition to, those taught in the Misra Publication.

The stack of thin film layers includes, for example, an electrically conductive back electrical contact layer disposed on the common substrate, a photovoltaic stack formed on the back electrical contact layer, and an electrically conductive front electrical contact layer disposed on the photovoltaic stack. The photovoltaic stack includes, for example, a solar absorber layer which generates electron-hole pairs in response to light incident thereon, and a heterojunction partner layer, such that the solar absorber layer and the heterojunction partner layer collectively form a p-n junction. Some examples of possible solar absorber layer materials include Copper-Indium-DiSelenide (CIS), or an alloy thereof, such as Copper-Indium-Gallium-DiSelenide (CIGS). Some examples of possible heterojunction partner layer materials include Cadmium Sulfide or an alloy thereof. Additional layers, such as buffer layers and/or stress relief layers, may be added to the stack of thin film layers without departing from the scope hereof. First bus bar 124 is electrically coupled to the back electrical contact layer, and second bus bar 126 is electrically coupled to the front electrical contact layer, in certain monolithically integrated embodiments.

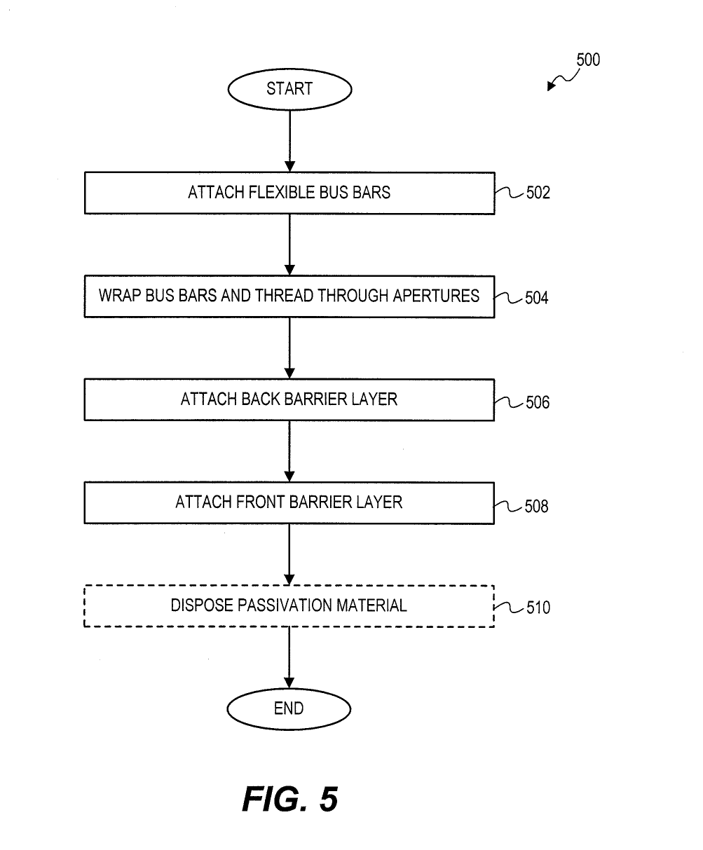

FIG. 5 shows a method 500 for forming a photovoltaic assembly. Method 500 is used, for example, to form photovoltaic assembly 100 of FIGS. 1-4. However, method 500 is not limited to forming this particular photovoltaic assembly. Additionally, photovoltaic assembly 100 could be formed by methods other than that of FIG. 5.

Method 500 begins with step 502 of attaching first and second flexible bus bars to respective electrical contacts on a front outer surface of a flexible photovoltaic module. One example of step 502 is attaching bus bars 124, 126 in the form of conductive tape to electrical contacts 120, 122 of photovoltaic module 102, using adhesive material of the conductive tape. In step 504, the first and second flexible bus bars are wrapped around the photovoltaic module and threaded through at least one aperture in a flexible back adhesion layer and through at least one aperture in a flexible back barrier layer. One example of step 504 is wrapping first bus bar 124 around module 102 and threading first bus bar 124 through apertures 128, 132 in back adhesion layer and back barrier layer 114, 110, respectively, as well as wrapping second bus bar 126 around module 102 and threading second bus bar 126 through apertures 130, 134 in back adhesion layer and back barrier layer 114, 110, respectively.

In step 506, the back barrier layer is attached to a back outer surface of the photovoltaic module using the back adhesion layer, where the back outer surface of the photovoltaic module opposes the front outer surface of the photovoltaic module. One example of step 506 is attaching back barrier layer 110 to module back outer surface 106 using back adhesion layer 114. In step 508, an optically transparent front barrier layer is attached to the front outer surface of the photovoltaic module using an optically transparent front adhesion layer. One example of step 508 is attaching front barrier layer 108 to module front outer surface 104 using front adhesion layer 112. In some alternate embodiments of method 500, step 508 is performed before step 506, or steps 506 and 508 are performed simultaneously. In optional step 510, a passivation material, such as encapsulant or a pottant, is disposed in the back adhesion layer and back barrier layer apertures, where the bus bars are threaded through the apertures. One example of step 510 is disposing a passivation material in back adhesion layer apertures 128, 130 and in back barrier layer apertures 132, 134.

Combinations of Features

Features described above as well as those claimed below may be combined in various ways without departing from the scope hereof. The following examples illustrate some possible combinations:

(A1) A photovoltaic assembly may include a flexible photovoltaic module, a flexible back barrier layer, and electrically conductive first and second flexible bus bars. The flexible photovoltaic module may include (a) opposing front and back outer surfaces and (b) first and second electrical contacts on the front outer surface. The photovoltaic module may be adapted to generate an electrical potential difference between the first and second electrical contacts in response to light incident on the front outer surface. The flexible back barrier layer may be disposed on the back outer surface of the photovoltaic module. The electrically conductive first and second flexible bus bars may be electrically coupled to the first and second electrical contacts, respectively, and the first and second flexible bus bars may wrap around the flexible photovoltaic module and extend through the back barrier layer.

(A2) In the photovoltaic assembly denoted as (A1), each of the first and second flexible bus bars may include electrically conductive tape.

(A3) In the photovoltaic assembly denoted as (A2), the electrically conductive tape may include electrically conductive metallic foil tape.

(A4) In either of the photovoltaic assemblies denoted as (A2) or (A3), the first and second flexible bus bars may be secured to the first and second electrical contacts, respectively, by adhesive material of the electrically conductive tape.

(A5) Any of the photovoltaic assemblies denoted as (A1) through (A4) may further include a back adhesion layer disposed between the back outer surface of the photovoltaic module and the back barrier layer.

(A6) In the photovoltaic assembly denoted as (A5), the first and second flexible bus bars may extend through one or more apertures in each of the back barrier layer and the back adhesion layer.

(A7) The photovoltaic assembly denoted as (A6) may further include a material selected from the group consisting of an encapsulant and a pottant disposed in the one or more apertures in each of the back barrier layer and the back adhesion layer.

(A8) Any of the photovoltaic assemblies denoted as (A1) through (A7) may further include an optically transparent, flexible front barrier layer disposed on the front outer surface of the photovoltaic module.

(A9) The photovoltaic assembly denoted as (A8) may further include an optically transparent, front adhesion layer disposed between the front outer surface of photovoltaic module and the front barrier layer.

(A10) In the photovoltaic assembly denoted as (A9), the front barrier layer may be substantially smooth.

(A11) In any of the photovoltaic assemblies denoted as (A1) through (A10), the flexible photovoltaic module may include the following: (a) a flexible substrate; (b) an electrically conductive back electrical contact layer disposed on the flexible substrate; (c) a photovoltaic stack disposed on the back electrical contact layer; and (d) an electrically conductive front electrical contact layer disposed on the photovoltaic stack.

(A12) In the photovoltaic assembly denoted as (A11), the front and back electrical contact layers and the photovoltaic stack may be patterned and connected to form a plurality of electrically-interconnected photovoltaic cells on the flexible substrate.

(A13) In either of the photovoltaic assemblies denoted as (A11) or (A12), the first flexible bus bar may be electrically coupled to the back electrical contact layer, and the second flexible bus bar may be electrically coupled to the front electrical contact layer.

(A14) In any of the flexible photovoltaic assemblies denoted as (A1) through (A13), the flexible photovoltaic module may include a plurality of photovoltaic cells monolithically integrated on a common substrate.

(B1) A method for forming a photovoltaic assembly may include the following steps: (a) attaching first and second flexible bus bars to respective electrical contacts on a front outer surface of a flexible photovoltaic module; (b) wrapping the first and second flexible bus bars around the flexible photovoltaic module; (c) threading the first and second flexible bus bars through at least one aperture in a flexible back adhesion layer and at least one aperture in a flexible back barrier layer; and (d) attaching the back barrier layer to a back outer surface of the photovoltaic module using the back adhesion layer, where the back outer surface of the photovoltaic module opposes the front outer surface of the photovoltaic module.

(B2) The method denoted as (B1) may further include attaching an optically transparent front barrier layer to the front outer surface of the photovoltaic module using an optically transparent front adhesion layer.

(B3) Either of the methods denoted as (B1) or (B2) may further include disposing a material selected from the group consisting of an encapsulant and a pottant in the at least one aperture in the flexible back adhesion layer and in the at least one aperture in the flexible back barrier layer.

(B4) In any of the methods denoted as (B1) through (B3), the first and second flexible bus bars may include metallic foil.

(B5) In any of the methods denoted as (B1) through (B3), the first and second flexible bus bars may each include electrically conductive tape, and the step of attaching the first and second flexible bus bars to respective electrical contacts on the front outer surface of the flexible photovoltaic module may include attaching the bus bars to the electrical contacts using adhesive material of the electrically conductive tape.

Changes may be made in the above methods and systems without departing from the scope hereof. For example, assembly 100 could be modified so that bus bars 124, 126 extend through one or more sides of assembly 100, instead of through back barrier layer 110, although such alternate configuration may provide inferior environmental protection to photovoltaic module 102. As another example, front and back barrier layers 108, 110 could alternately be secured to photovoltaic module 102 using means other than or in addition to adhesion layers. It should thus be noted that the matter contained in the above description and shown in the accompanying drawings should be interpreted as illustrative and not in a limiting sense. The following claims are intended to cover generic and specific features described herein, as well as all statements of the scope of the present method and system, which, as a matter of language, might be said to fall therebetween.

What is claimed is:

1. A photovoltaic assembly, comprising:
a flexible photovoltaic module including opposing front and back outer surfaces, the photovoltaic module including first and second electrical contacts on the front outer surface, the photovoltaic module adapted to generate an electrical potential difference between the first and second electrical contacts in response to light incident on the front outer surface;
a flexible back barrier layer disposed on the back outer surface of the photovoltaic module; and
electrically conductive first and second flexible bus bars electrically coupled to the first and second electrical contacts, respectively, the first and second flexible bus bars wrapping around the flexible photovoltaic module and extending through the back barrier layer.

2. The photovoltaic assembly of claim 1, each of the first and second flexible bus bars comprising electrically conductive tape.

3. The photovoltaic assembly of claim 2, further comprising a back adhesion layer disposed between the back outer surface of the photovoltaic module and the back barrier layer.

4. The photovoltaic assembly of claim 3, further comprising an optically transparent, flexible front barrier layer disposed on the front outer surface of the photovoltaic module.

5. The photovoltaic assembly of claim 4, further comprising an optically transparent, front adhesion layer disposed between the front outer surface of photovoltaic module and the front barrier layer.

6. The photovoltaic assembly of claim 5, the flexible photovoltaic module comprising:
a flexible substrate;
an electrically conductive back electrical contact layer disposed on the flexible substrate;
a photovoltaic stack disposed on the back electrical contact layer; and
an electrically conductive front electrical contact layer disposed on the photovoltaic stack,
wherein the front and back electrical contact layers and the photovoltaic stack are patterned and connected to form a plurality of electrically-interconnected photovoltaic cells on the flexible substrate.

7. The photovoltaic assembly of claim 6, the first flexible bus bar being electrically coupled to the back electrical contact layer, and the second flexible bus bar being electrically coupled to the front electrical contact layer.

8. The photovoltaic assembly of claim 7, the front barrier layer being substantially smooth.

9. The photovoltaic assembly of claim 6, each of the first and second flexible bus bars comprising electrically conductive metallic foil tape.

10. The photovoltaic assembly of claim 6, the first and second flexible bus bars being secured to the first and second electrical contacts, respectively, by adhesive material of the electrically conductive tape.

11. The photovoltaic assembly of claim 3, the first and second flexible bus bars extending through one or more apertures in each of the back barrier layer and the back adhesion layer.

12. The photovoltaic assembly of claim 11, further comprising a material selected from the group consisting of an encapsulant and a pottant disposed in the one or more apertures in each of the back barrier layer and the back adhesion layer.

13. The photovoltaic assembly of claim 1, the flexible photovoltaic module comprising a plurality of photovoltaic cells monolithically integrated on a common substrate.

14. A method for forming a photovoltaic assembly, comprising:
attaching first and second flexible bus bars to respective electrical contacts on a front outer surface of a flexible photovoltaic module;
wrapping the first and second flexible bus bars around the flexible photovoltaic module;
threading the first and second flexible bus bars through at least one aperture in a flexible back adhesion layer and at least one aperture in a flexible back barrier layer; and
attaching the back barrier layer to a back outer surface of the photovoltaic module using the back adhesion layer, the back outer surface of the photovoltaic module opposing the front outer surface of the photovoltaic module.

15. The method of claim 14, further comprising attaching an optically transparent front barrier layer to the front outer surface of the photovoltaic module using an optically transparent front adhesion layer.

16. The method of claim 14, further comprising disposing a material selected from the group consisting of an encapsulant and a pottant in the at least one aperture in the flexible back adhesion layer and in the at least one aperture in the flexible back barrier layer.

17. The method of claim 14, the first and second flexible bus bars comprising metallic foil.

18. The method of claim 14, wherein:
the first and second flexible bus bars each comprise electrically conductive tape; and
the step of attaching the first and second flexible bus bars to respective electrical contacts on the front outer surface of the flexible photovoltaic module comprises attaching the bus bars to the electrical contacts using adhesive material of the electrically conductive tape.
